(19) United States
(12) Patent Application Publication
(10) Pub. No.: US 2015/0020865 A1
(43) Pub. Date: Jan. 22, 2015

(54) Methods and apparatus for Inflatable concentrated solar energy station/balloon and self supporting cable

(71) Applicant: QUAN XIAO, Beijing (CN)

(72) Inventor: QUAN XIAO, Beijing (CN)

(21) Appl. No.: 13/944,305

(22) Filed: Jul. 17, 2013

(51) Int. Cl. H01L 31/052; G02B 19/00

(52) U.S. Cl. CPC H01L 31/0525; G02B 19/0042
USPC 136/246; 359/853

(57) ABSTRACT

With the new development of clean energy technology, there are more and more demand for concentrated solar energy to provide lightweight, cost-effective power and thermal generation. There's also a (separated) requirement to transmit power/energy effectively. The current invention including using a unique inflatable structure to concentrate solar energy, and made possible to create a balloon type solar power station to capture solar power above the ground. It also provides a self supporting cable solution for power transmission that overcomes the obstacles of supporting the weight of the cable and also be able to overcoming/reduce the wind drag related load to the cable.

### CROSS REFERENCE TO RELATED APPLICATIONS

The present application claims priority from U.S. Provisional Patents Application Ser. Nos. US 61/741,320 and 61/741/321 both filed on Jul. 17, 2012. The full disclosures of which are hereby incorporated by reference herein.

### TECHNICAL FIELD

The present invention relates to concentrate solar energy for power generation and/or heating, and also relates to ways and apparatus to transfer power.

### BACKGROUND INFORMATION

With the new development of clean energy technology such as solar power, there are more and more demands for concentrated solar energy to provide lightweight, cost-effective power and thermal generation. There's also a (related but separated) requirement to transmit power/energy effectively. While wireless transmission from high altitude to the ground has many desirable features, currently the technology has major drawbacks such as lower efficiency, high cost on transmitting and receiving related systems, and low energy-density when compared with wired transmission. However, for wired transmitting with altitude difference, such as but not limited to from the high altitude wind or solar generator to ground, obstacles like supporting the weight of the cable and overcoming wind drag cable needs to be resolved.

### BRIEF DESCRIPTION OF DRAWINGS

FIG. 1 and FIG. 2 shows 2 embodiments of the inflatable solar power station/balloon.

FIG. 1 shows an inflatable solar power station that have 2 compartments, inflated with pressure P1 and P2 respectively. The Pressure difference keep the reflective surface/membrane 102 in a correct shape for concentrating the sun light, such as but not limited to (concave) spherical, parabolic, and etc. Since the requirement for the accuracy is not very high, there could be many possibilities. The balloon have a transparent part of surface 101, which is in front of the reflecting surface, that allows sun light in, while other part (107) behind the reflecting surface 102 could be opaque. Supporting structures 104 support the energy/power generation unit 103 to the focus of the concentrated sun light. There could be a heat sink 105 on the back side of the reflecting surface.

FIG. 2 shows a slightly different design, with only one inflatable compartment, and the pressure inside keep the shape of reflecting surface 102. Other things such as power generating units and supporting structure are similar with FIG. 1 so not shown.

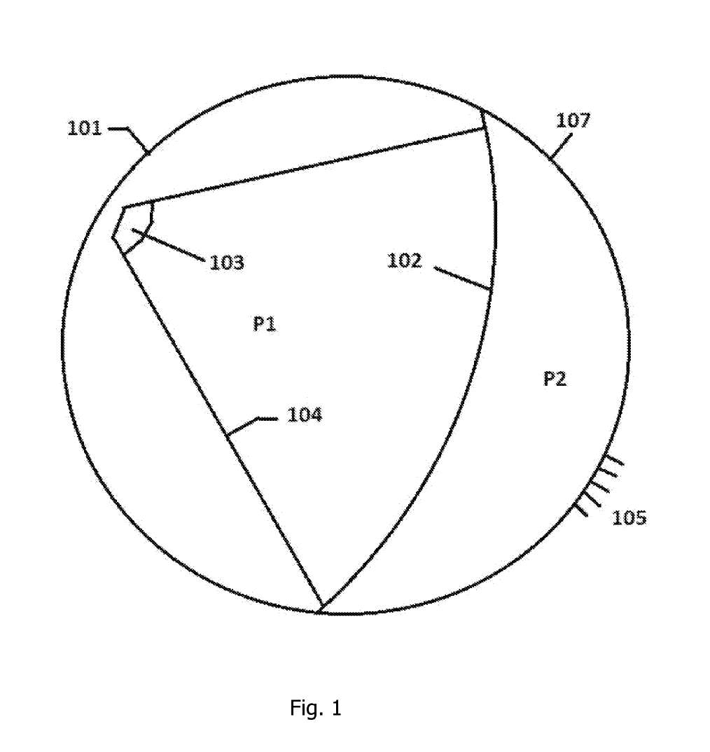

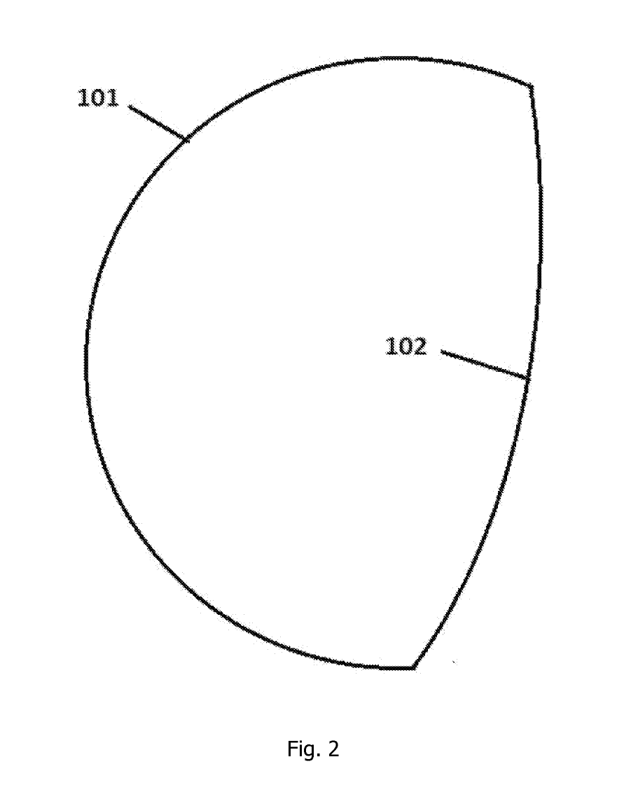

### DETAILED DESCRIPTION OF SPECIFIC EMBODIMENTS

An apparatus for concentrate solar energy for power generation and/or heating. Main feature including:

Inflated design. Have an enclosure of surface so that it could be inflated The pressure maybe used to keep the shape, for example the external shape, the shape of an reflective surface inside the outer layer, etc.

A method might use certain kind of gas for example those light than air such as Hydrogen, Helium, or Hot air, or mixture of gas(s) to inflate, so that to provide buoyancy, so that it can be lightweight and float in the air, and be used in situations like high altitude blimp for power generation.

The inflated apparatus has one or more partially transparent part(s) to let sun light in.

The above mentioned inflated apparatus also has one or more—reflective surfaces, for example but not limited to: have a reflective wall or membrane(s), these reflective surfaces are in a shape that concentrate sunlight (such as spherical, parabolic and etc.)
the air pressure/pressure difference in the inflated apparatus might be used to held the shape of the reflective device. However the concentrator shape might be held in other ways such as 1) dynamic pressure (blowing air) 2) negative pressure 3) pre-stressed elastic materials/memory materials 4) pre-shaped materials and etc.

The shape could also be pre-fabricated with light weight material(s)

it is desirable to have tracking systems and means to turn the inflated apparatus, such as but not limited to something using aerodynamics such as rudder/airfoil/controlling surfaces, something using thrust vectoring such as fans/propellers (might change direction)some ground based tracking system, such as but not limited to Equatorial tracking, Altazimuth tracking for the diurnal motion and etc.

Tracking system can make several of these units into a group, to further concentrate solar power.

It is desirable to have/use PV(Photovoltaic) combined with Heat exchange, thermal generation system integrated. A high efficiency system could be achieved by concentrate the solar ray to the PV component and using the heat from the coolant of the PV component to generate electricity, steam or other usage. The combination would provide higher energy conversion efficiency than any of the single methods.

Optionally the apparatus could have a heat sink, and it can be located at the back side of the reflector/concentrator

May have multiple lenses/mirror to correct path and shape/focal. These lenses/mirror(s) maybe (but not limited to) shaped by the pressure differences between chambers of the inflated apparatus

Can use cable/Fiber optic-cable to send electric power or light energy to other places

Can have energy storage

Can create by product in the process using the energy for example to “harvest” “separate” or “split compounds”, such as cryogenic fuel, water split to H2, O2, harvest scared gasses, and etc.

Similarly, a method for concentrating solar radiation to generate heat, electricity and other products, including:

Forming an enclosing which is inflatable, using certain kind of gas(s) to inflate, so that the enclosing (and membranes inside it) formed certain shape (for example sphere or parabolic) that facilitate concentration of solar energy.

It could have multiple compartments. They might be inflated with different pressure.

It might (optionally) to provide buoyancy, such as but not limit to those light than air such as Hydrogen, Helium, or Hot air, or mixture of gas(s) so that it can be used in situations like high altitude blimp.

There could be sensors to monitoring the pressure and/or shapes.

There could be may solutions/implementations details and the method/apparatus are merely examples to explain the idea of the invention.

As the suitable means/methods for the above discussion may be embodied in a wide variety of forms, some of which may be quite different from those of the disclosed embodiment. Consequently, the specific structural and functional details disclosed herein are merely representative;

A cable like apparatus can be used for:

Transmission of energy such as but not limit to: electric power, light and etc. for example from high altitude wind power generator to the ground and/or (optionally) (tethering) tension control for holding/attaching the aerial component to ground (so that it wont be blown away by wind), for example in a way similar to those methods to fly a kite.

The cable like apparatus having the following features:

1. self-supporting: it can at least partially support its own weight—By means such as buoyancy, lift, thrust, or the combination, etc. These forces might be used on sections of the cable-like apparatus.

2. Flexible and at least partially controllable, for example how to support its own weight, and/or how much it will support, and/or other aspects such as the shape/moving direction of the cable.

3. Cold have 1 or multiple conduits (for energy transmission).

(Similarly, a method to supporting a cable like apparatus can have features in the above mentioned situations.)

Optionally, the sections of the cable can form/maintain formations according to different requirements or situations.

In one embodiment the cable like apparatus may have some wire/cable reserved on the ground for example in a winch/capstan, so that length and tension could be controlled.

The cable like apparatus could have/include one or more sections. There could be from zero to many “nodes” on each section. Those nodes can serve the purpose such as controlling, sensing, providing lift/buoyancy/thrust or the combination of any of the mentioned above, tension adjustment, thrust vectoring (flight control) and etc.

some of the node(s) might be performing single tasks or passive activities, we can call them “passive node”, such as the node made up of a balloon/blimp or kite/passive wing, so the role of that node is just to provide buoyancy/lift or similar function, while some other nodes might be active-control node such as with control surfaces (/rudder/airfoil), have rotor wing/propeller/fan/jet/nozzle that can change speed/rotation directions/axial direction and etc so that to provide control forces (and maybe as well as lift/buoyancy/thrust)and more flexibility in operations.

There are different methods/forms can be use to provide buoyancy/lift/thrust/jet or other kind of forces, so that the “cable like apparatus” can at least partially support its own weight. The methods/forms could be such as but not limited to: Buoyancy provided by lighter than air devices such as balloon(s), blimp(s) and etc, Lift provided by Wing(s), Rotating Wing(s), or thrust/jet by propeller(s), Fan(s), Jet(s), nozzle(s) and etc, or the mixture of the methods

It is desirable that the power (energy source) for the nodes can come from “bleeding” (use a part of) or “extracting a part of” the power being transmitted in the “cable like apparatus”, or, the node(s) can have power source themselves, such as battery cells, fuels, fuel cells, solar cells, (small) wind generator/turbine, generators, receivers for ground based wireless energy transmitters (such as laser or micro wave) and other forms, it can also have/employ a mixture of the above mentioned forms or methods. One benefit of the mixing self carried battery cell/generator/wireless energy receiver or other kind of energy storage with power generation or power bleeding means is that when those power generation or power bleeding means become unavailable or unstable, the battery cell/energy store/generator/wireless energy receiver can provide backup in case of emergency, it is also possible they can be used collectively, as a backup/emergency power source.

It is desirable that other things such as control signal, light and etc can be transmitted besides power/other kind of energy in the in the cable-like apparatus.

Directional-wise it is desirable that the signal and/or power can be transferred/transmission in both directions in the cable-like apparatus.

In one embodiment the cable like apparatus could also link to other cable like apparatus.

In one embodiment, Optionally, the nodes/segments could work collectively/collaborative, or they can work independently, or combined. They might be remote controlled, manually controlled, work autonomously or mixed forms (for example, different method/form in different times/situations).

It is desirable that the cable-like apparatus can sense and control the tension to prevent the cable/wire of power transmission from broken, and ensure safety. (For example Force/Stress Sensors and/or video cameras can be used for tension sensing purpose), and winch/capstan or other kind of actuators can be used to adjust tension. It is also possible the nodes (especially active control nodes which can provide active control forces and/or movements) can be moved or the formation of the nodes being adjusted to keep tension within some desired range (or to avoid excessive wind load). This could be similar to the capstan/anchoring machine adjusting tension when ship is tethered to the shore/anchoring, a control solution similar to these situation might be used. The above discussion served merely as example as there could be a lot of different solution/method that can achieve the purpose.

In one embodiment It is desirable other sensors such as for atmospheric data (temperature, wind-speed, pressure) and etc. to be built in to monitoring situations of all nodes/sections in real time.

In one embodiment it is desirable the cable-like apparatus allowing twist, or turn/twist between sections. There could be many ways to prevent over twisting of the cable such as but not limited to: employ a “coaxial” design in the connectors to join the 2 sections, so that each section can easily turn individually without twisting.

In one embodiment it is desirable that sections are capable of being grouped, re-grouped, re-linked/re-connected when needed. One example solution could be (but not limited to) that they can be treated like nodes in a (computer) network. Group control strategy/algorithms might be applied to coordinate them to work together (collectively). Alternatively, they can also be controlled individually, by means such as remote control, manual control. It can also be viewed as individual part linked together. Many related algorithms or the mix of the algorithms can be used to control the node(s) of “cable-like apparatus”.

In one embodiment it is desirable the active nodes/sections being controlled as a group or groups. Different group control strategy can be used. For example some “local” strategy of leader and followers can be used to form/keep a formation and/or to adjust tension etc. Other strategies (for example for multi-vehicle control) such as but not limit to information consensus strategy, distributed coordination architecture for multi vehicle formation control, adaptive guidance and control based on passive(and/or active) detection, Compliant Formation Control, and etc could also be used.

In one embodiment manual intervention may be allowed, especially for leader(s) in the group, if there's any.

In one embodiment the “active control” node can have multiple sensors, for example by GPS for position/altitude. The nodes might be able to get other kind of positioning/navigational signal in order to position itself, alternatively, they can give out signal/reflect signals, so that (external) positioning systems can locate its position. The node(s) could also have other instrument/sensors for (gathering) fly control/atmospheric data computing related parameters such as relative airspeed/wind speed, air temperature and pressure, air flow direction, etc. can have inertia-directional (compass) sensors, these sensors can be used in the control of the node or near by (not necessary neighboring) nodes. The nodes with proper information (such as those mentioned above) and controlling means such as (but not limited to) controlling surfaces (rudder/airfoil), fans/propellers/jets/nozzles that can change directions, buoyancy control means and etc, can (optionally) have some autonomous control, if the node is not completely controlled in a centralized control system.

In a common case with a centralized control, and each section might have a degree of autonomous. Each section might expose certain key functions in one or more “interface” to the centralized control system, and they might different implementations of the interface (like the concept in computer science). They can exchange position information/sensor readings and other information to work collaboratively. The architecture could be organized like using network for control of each node, and desirably nodes can be added/removed to network, for example dynamically. There could be several level/multi-leveled of protocol/interfaces.

Like modern UAV/model plane/helicopter control system, inertia/compass/gyro sensors, GPS and other sensors can be integrated, to provide integrated control on “pose”, direction/orientation (6DOF, 9DOF) control, self-balancing and stability control, “auto piloting”/autonomous flight control and etc. Since they are pretty common for UAV system/air models/multi-copter system, it is not difficult to implement similar control for the active control nodes.

It is also proved possible that with different group control strategies, multiple autonomous nodes (maybe controlled like an UAV,) can be organized/coordinated to maintain/change formations.

Nodes (especially active control nodes) might have docking means/mechanism for reconnect to other nodes, such as but not limit to: external plug/socket/interface so that they can be re-connect (either through the original socket/connector, or the 2ndary socket/connector, might only provide part of the capability/function in the emergency mode) The technology used might be similar to that of air refueling or manual/automatic docking of spaceship. Tracking of the relative position, approaching and capturing will be performed.

There could be multiple strategies for overcoming the cable/wire broken situation: one is to carry backup wire/cable, which means some key nodes carrying redundant wires/cables, either already between them or can be deployed at emergency time. In these situations the part above the broken point would use backup line to connect to lower part, and do not need to lower the altitude. Another strategy uses existing “unbroken” segments/sections; basically reconnect with survival nodes/segments. It could be either the upper section descending/lowering altitude in order to re-join the lower part, or the lower part raises altitude (maybe with more wire feed from the ground) to meet the upper part. At least one remotely or autonomously controllable (or active) nodes would be used for re-connection.

It is desirable some nodes having a socket or docking mechanism (so that it can be connected to another node during flight/in the air. They might be for example similar to that of air-refueling or spaceship docking mechanisms, or they might have robot arm/remote controlled actuators or other “capture means” (like those used in air re-fueling or ISS to help spaceship docking) to help capturing and docking/re-connection.

It is desirable, although not required that each node could store some energy so that in case cable broken they can collectively provide power to the upper nodes (and/or other systems attached to the cable like apparatus) for a short period of time.

Optionally upper part can descend and/or directly shoot/release wires to the ground, so that the ground could link/hookup and re-connect to it quickly. This would not need aerial reconnect, but the upper portion would need to carry some amount of backup wire.

It is desirable wireless communication can substitute wired communication when needed (such as in case wired communication is broken).

It is desirable some of the “active control nodes” can fly autonomously or by remote control to provide multiple degree of freedom movement, so that to re-connect with other sections, if necessary. (Technology similar to UAV can be used)

Because the active node is (usually) attached to the cable and usually operates near the cable/wire, vehicle design of certain forms might be advantageous, for example a tandem rotor wings/propellers, contra-rotating rotor/propellers, multiple (smaller diameter) rotors/propellers like the multi copter, enclosed/shrouded fans or rotor/propeller with shroud/enclosed to prevent accidental caught the wire. Also multiple balloons/blimps might be some other embodiment to provide balanced buoyancy. To reduce wind drag, balloons/blimps may have fans/propellers to provide thrust, or they might be able to change shape, for example but not limit to, reduce size, become lower-profile to cross wind, being compressed or deflated, and etc.

It is desirable some of the sections can be controlled (or autonomously) to re-link/couple with next or some desired section in certain situations, such as but not limited to some part of the (broken) cable, this is provided by the above mentioned node, or we can use external helicopter/multi-copter/UAV/Blimp to help to perform the re-connection.

In one embodiment, the active node is able to move along the wire/cable and remain attach to it. This can be implemented for example by some clamping device, some confine/restraint mechanism for example using wheels or bearings, and etc. The node could “climb” up and down along the wire, to perform desired job such as maintenance, checking, re-connections and etc.

In one embodiment it is desirable platform or node(s) is capable of (selectively) connect to other Objects in the air, such as UAV, plane, Blimp for safety-backup power etc.

When connect to other UAV/Helicopter/Multi copter/Blimp, they can be seem as part of the system as a “Grid”/Node to provide Buoyancy/Lift/thrust, direction control, wind drag reduction or neutralization, and etc. They can also release/separate with the system.

In one embodiment it is desirable that The cable-like apparatus have tension control, for example using winch/capstan (and might reserving multiple loops of wire/cable) and release/contract according to tension, this can be done at the node level, section level, or the whole cable level, or the mix.

In one embodiment the cable-like apparatus might have special coating like anti-ice coating, anti-static coating. It might also have de-icing devices for example using acoustic/ultrasound, thermal heat and etc. It might have means for discharging lighting energy if struck or ways to prevent it being strike.

Similarly, a method of transmitting energy between aerial system (such as but not limit to: wind generator or solar generator and etc.) and ground, by supporting each section of the cable with buoyancy or lift or thrust or any of the combination, so that the entire weight of the cable is not “applied to” or supported by any single point of the cable. The weight is supported “collectively” by the nodes/sections of the cable.

A method to provide energy transmitting between 2 different altitudes for purpose such as but not limited to high altitude wind/solar generation includes:

Combining active sections which provide ways to supporting its own weight (or a portion of it), by means not limited to: lift, buoyancy, thrust or the combination, the combined section forming a cable like structure, which is flexible and partially controllable, and have conduit(s) for energy transferring

As the suitable means/methods for the above discussion may be embodied in a wide variety of forms, some of which may be quite different from those of the disclosed embodiment. Consequently, the specific structural and functional details disclosed herein are merely representative; yet in that regard, they are deemed to afford the best embodiment for purposes of disclosure and to provide a basis for the claims herein which define the scope of the present invention.

Discussion of One Example Embodiment:

The cable like apparatus is linked to a floating high altitude turbine/solar generator/concentrated solar power station, which lifted by balloons or itself is a blimp.

The “cable like apparatus” comprised of multiple sections (and with one end attached to the ground).

Each section, have one or more active control node(s) which could provide control force as well as lift/buoyancy/thrust, some might be inform of blimp/airship, or with propeller/rotor wing/fan/jet/nozzle, or might be combined the above mentioned forms. Each section could also have passive nodes which just provide lift/buoyancy/thrust.

The active nodes could be autonomous and in a group to maintain a certain formation, or simply hang on to each other, and control tension to prevent breaking the wire/cable. The active nodes might also be remote controllable, and be controlled centrally.

It could have winch/capstan, and multiple loop of wire reserved on the winch/capstan so that in case the tension of the wire is over a certain limit, winch/capstan will release some wire to prevent it broken.

The active nodes and some of the passive nodes have docking means/mechanism such as plugs and sockets, so that it can connect to other nodes when needed.

The connection/connector or some part of the section (not necessarily each section) could have “co-axial” design so that cable could turn without twist.

In one embodiment, the active node extract or “bleed” from the cable to get energy, however optionally it is possible it have its own energy reserve/batteries

One example strategy might be, the aerial platform as “leader”, and the active nodes below it as follower, to form a “flocking” or “consensus based” group strategy. In such case when leader moves, follows will move accordingly to maintain a certain formation, so that the distances between them and relative position are relatively unchanged, thus wire's tension wont change greatly.

In case of wire broken, some emergency procedure will kick in while the group strategy will be paused/changed to adapt to the requirement of new situation. First a fast scan of all nodes/sections will be performed to locate the break point/section. Attempt to reconnect with backup channel such as in wireless to those above the break point (which loses wired connections), it could be centralized (top down from the aerial platform) or distributed. Then a re-connection will be attempted.

By either lower the entire upper section which above the break point one or more sections down, the lowest good active node of upper section will try to establish connection with the upper nodes of the lower section. As an alternative, some redundant nodes of the lower part might fly up to search for connectable “docks” for re-connection.

With technology similar to aerial refueling or spaceship docking, re-connection between 2 nodes in air is possible, some robotic arm might help to do so.

There could be may solutions/implementations details and the method/apparatus are merely examples to explain the idea of the invention.

1. A solar power concentration apparatus comprised of:
a. at least one enclosed surface which could be inflated with gas or mixture of gas, in which the pressure maybe used to keep/hold the shape, for example including but not limited to: the external shape, the shape of an reflective surface inside the outer layer, etc;
b. has at least one transparent part(s)/portion of the surface to let sun light in;
c. at least one reflective surfaces, for example but not limited to: have a reflective wall or membrane(s), these reflective surfaces are in a shape that concentrate sunlight (such as spherical, parabolic and etc).

2. An apparatus according to claim 1, wherein the shape of the reflective device is held by one or the combination of the following:
a) air pressure/pressure difference in the inflated apparatus might be used to held;
b) dynamic pressure (blowing air);
c) negative pressure;
d) pre-stressed elastic materials/memory materials 4) pre-shaped materials and etc;
e) pre-fabricated/pre-stressed light weight material(s).

3. An apparatus according to claim 1, wherein the light-than-air gas being used to inflate such as one or combination of the following: Hydrogen, Helium, or Hot air, or mixture of gas(s), so that buoyancy can be provided at the same time.

4. A solar power concentration apparatus according to claim 1, further comprised of:
tracking systems and means to turn the inflated apparatus, such as but not limited to something using aerodynamics such as rudder/airfoil/controlling surfaces, something using thrust vectoring such as fans/propellers (might change direction)some ground based tracking system, such as but not limited to Equatorial tracking, Altazimuth tracking for the diurnal motion and etc.

5. A cable like apparatus for the power/energy transmission comprised of:
a. Means for supporting at least partial of the cable's weight, such as but not limited to: means to provide buoyancy, means to provide lift, means to provide thrust, or the combination, and etc. These forces might be used on sections of the cable-like apparatus;
b. cable to transfer power/energy which is flexible and at least partially controllable, for example how to support its own weight, and/or how much it will support, and/or other aspects such as the shape/moving direction of the cable;
So that the weight supporting means support the cable while the cable transferring power/energy.

6. An apparatus according to claim 5, wherein the cable comprised of least 1 or multiple conduits for power/energy transmission.

7. An apparatus according to claim 5, wherein sections of the cable is capable of selectively forming maintaining formations according to different requirements or situations.

8. An apparatus according to claim 5, further comprised of: length and tension controlling means/mechanism such as winch/capstan, and some reserved wire/cable for example on the ground.

9. An apparatus according to claim 5, wherein the cable like apparatus could have/include one or more sections. There could be from zero to many “nodes” on each section. Those nodes can serve the purpose such as controlling, sensing, providing lift/buoyancy/thrust or the combination of any of the mentioned above, tension adjustment, thrust vectoring (flight control) and etc. Some of the node(s) are “passive node” where single task or “passive” activities/function is performed, such as just to provide buoyancy/lift or similar function, by means of balloon/blimp or kite/passive wing;
while some other nodes might be active-control node such as with control surfaces (/rudder/airfoil), have rotor wing/propeller/fan/jet/nozzle that can change speed/rotation directions/axial direction and etc so that to provide control forces (and maybe as well as lift/buoyancy/thrust)and more flexibility in operations.

10. An apparatus according to claim 5, wherein the active nodes/sections can be controlled as a group or groups. Different group control strategy can be used. For example some “local” strategy of leader and followers can be used to form/keep a formation and/or to adjust tension etc. Other strategies (for example for multi-vehicle control) such as but not limit to information consensus strategy, distributed coordination architecture for multi vehicle formation control, adaptive guidance and control based on passive(and/or active) detection, Compliant Formation Control, and etc could also be used.

11. An apparatus according to claim 5, wherein manual intervention may be allowed, especially for leader(s) in the group, if there's any.

12. An apparatus according to claim 5, wherein the “active control” node can have multiple sensors, for example by GPS for position/altitude. The nodes might be able to get other kind of positioning/navigational signal in order to position itself, alternatively, they can give out signal/reflect signals, so that positioning systems can locate its position. it could also have other instrument/sensors for (gathering) fly control/atmospheric data computing related parameters such as relative airspeed/wind speed, air temperature and pressure, air flow direction, etc. can have inertia-directional (compass) sensors, these sensors can be used in the control of the node or near by (not necessary neighboring) nodes. The nodes with proper information (such as those mentioned above) and controlling means such as (but not limited to) controlling surfaces (rudder/airfoil), fans/propellers/jets/nozzles that can change directions, buoyancy control means and etc, can (optionally) have some autonomous control, if the node is not completely controlled in a centralized control system;
In a common case with a centralized control, and each section might have a degree of autonomous. Each section might expose certain key functions in one or more “interface” to the centralized control system, and they might different implementations of the interface (like the concept in computer science). They can exchange position information/sensor readings and other information to work collaboratively. The architecture could be organized like using network for control of each node, and desirably nodes can be added/removed to network, for example dynamically. There could be several level/multi-leveled of protocol/interfaces.

13. An apparatus according to claim 5, wherein control system, inertia/compass/gyro sensors, GPS and other sensors can be integrated similar to those in modern UAV/model plane helicopter, to provide integrated control on “pose”, direction/orientation (6DOF, 9DOF) control, self-balancing and stability control, “auto piloting”/autonomous flight control and etc. Since they are pretty common for UAV system/model plane/multi copter system, it is not difficult for people familiar with the field to implement similar control for the active control nodes.

14. An apparatus according to claim 5, wherein nodes (especially active control nodes) might have docking means/mechanism for reconnect to other nodes, such as but not limit to: external plug/socket/interface so that they can be re-connect (either through the original socket/connector, or the 2ndary socket/connector, might only provide part of the capability/function in the emergency mode) The technology used might be similar to that of air refueling or manual/automatic docking of spaceship. Tracking of the relative position, approaching and capturing will be performed.

15. A method of transmitting energy between different altitude comprised of: (including)
supporting each section of the cable with buoyancy or lift or thrust or any of the combination, so that the entire weight of the cable is not “applied to” any single point of the cable. The weight is supported “collectively” by the nodes/sections of the cable, and using the cable to perform power/energy transmission.

16. A method to provide energy transmitting between 2 different altitudes for purpose such as but not limited to high altitude wind/solar generation includes:
Combining active sections which provide ways to supporting its own weight (or a portion of it), by means not limited to: lift, buoyancy, thrust or the combination, the combined section forming a cable like structure, which is flexible and partially controllable, and have conduit(s) for energy transferring.

17. A method according to claim 15, including transmitting the power/energy for lifting the cable through the cable and extract/“bleed” those power/energy at the place where supporting means use those energy/power to support the cable.

18. A method according to claim 16, further includes: using different group control strategies, multiple autonomous nodes (maybe controlled like an UAV,) to organized/coordinated to maintain/change formations.

19. A method according to claim 15, further includes: performing reconnection to other nodes, such as but not limit to: external plug/socket/interface so that they can be re-connect (either through the original socket/connector, or the 2ndary socket/connector, might only provide part of the capability/function in the emergency mode), using technology might be similar to that of air refueling or manual/automatic docking of spaceship, or performing tracking of the relative position, approaching and capturing to reconnect.
